(19) United States
(12) Patent Application Publication
(10) Pub. No.: US 2009/0236744 A1
(43) Pub. Date: Sep. 24, 2009

(54) SEMICONDUCTOR DEVICE AND METHOD OF PRODUCING THE SAME

(76) Inventor: Takao Kinoshita, Hiroshima (JP)

Correspondence Address: NIXON & VANDERHYE, PC, 901 NORTH GLEBE ROAD, 11TH FLOOR, ARLINGTON, VA, 22203, US

(21) Appl. No.: 11/885,405

(22) PCT Filed: Feb. 23, 2006
(86) PCT No.: PCT/JP2006/003296

§ 371 Date: Aug. 30, 2007

(30) Foreign Application Priority Data
Mar. 2, 2005 (JP) 2005-058007

(51) Int. Cl. H01L 23/532; H01L 21/768

(52) U.S. Cl. 257/751; 438/643; 257/E23.161; 257/E21.584

(57) ABSTRACT

A semiconductor device having a copper interconnection with high electromigration resistance is provided. A semiconductor device of the present invention includes an interconnection layer formed by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer comprises a plurality of layers including a small grain layer and a large grain layer, having different crystal grain sizes from each other, and the small grain layer is in contact with the barrier layer.

### TECHNICAL FIELD

The present invention relates to a semiconductor device and a method of producing the same.

### BACKGROUND ART

An LSI, in which elements such as a field-effect transistor and the like are integrated on a silicon substrate, has been miniaturized for higher speed or lower power consumption. The miniaturization of LSI has been advanced based on a scaling law, and interconnections have also been made higher in density, multi-layered, and thinner. Therefore, the stress applied to the interconnections and a current density flowing through the interconnections has increased and break of the interconnections due to electromigration has become a problem.

Conventionally, as an interconnection material of LSI, aluminum (Al) has been employed. In order to improve an electromigration resistance of the interconnection, addition of impurities such as copper or silicon to aluminum, or lamination in which an Al interconnection layer is sandwiched between high melting point metals such as titanium nitride (TiN), titanium (Ti) and the like have been conducted.

However, due to problems of a signal transmission delay and an allowable current density depending on the resistibility of Al, copper has started to be employed as alternative interconnection material, and interconnections have started to be formed of copper as a conductive material.

Since copper has difficulties in microprocessing by dry etching, processing methods which have been used for forming Al interconnections cannot be applied to copper. Therefore, a damascene process is adopted (for example, Patent Document 1). In the damascene process, a buried interconnection is formed by forming a groove for interconnection or a connecting hole between interconnections in an interlayer dielectric film, filling copper into the groove and the connecting hole, and removing unnecessary copper by a CMP method.

Copper has a higher melting point and larger self-diffusion energy than Al. Therefore, a lamination structure in which copper is sandwiched between high melting point metals is expected to show excellent electromigration resistance. However, in a buried interconnection structure, interface diffusion between a barrier layer and a copper layer is dominant, and improvement of reliability is difficult to accomplish.

Further, in forming copper damascene interconnections, it is necessary to fill copper into a via hole or a groove with a high-aspect ratio with high reproducibility. In general, a method, in which a laminated thin film of the barrier layer and the copper layer is formed and thereafter a copper film is formed by an electrolytic plating method, is employed. However, the copper film formed by an electrolytic plating method is involved with a self-annealing phenomenon, in which a crystal size or a concentration of impurities changes during storage at room temperature, and changes in polishing rate in a CMP process is generated. Therefore, a modification of a film by a heat treatment is required. However, a crystal structure of copper is changed in this heat treatment, and an adhesion property of the barrier layer to the copper layer may be deteriorated. If the adhesion property of these layers is deteriorated, copper atoms become apt to move around an interface between the barrier layer and the copper layer, and the electromigration resistance can be deteriorated.

### Patent Document 1: Japanese Unexamined Patent Publication No. 11-297696

### DISCLOSURE OF THE INVENTION

### Problems to be Solved by the Invention

The present invention was made in view of the above state, and it is an object of the present invention to provide a semiconductor device having a copper interconnection layer with high electromigration resistance.

### Means for Solving the Problems and Effects of the Invention

A semiconductor device of the present invention is a semiconductor device comprising an interconnection layer formed by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer comprises a plurality of layers including a small grain layer and a large grain layer, having different crystal grain sizes from each other, and the small grain layer is in contact with the barrier layer.

The present invention is particularly characterized in that the small grain layer is in contact with the barrier layer. The following principal is considered to explain the reason why the copper interconnection layer having high electromigration resistance is obtained in accordance with the present invention.

Since the crystal grain of the small grain layer has a smaller grain size and a smaller gap between crystal grains than the crystal grain of the large grain layer, the small grain layer is unlikely to aggregate in a heat treatment. Therefore, the small grain layer is unlikely to change in volume or change in crystal structure in a heat treatment. Therefore, a state of the interface between the barrier layer and the small grain layer is unlikely to be affected by the heat treatment, and a high adhesion property between the barrier layer and the small grain layer is maintained. Further, in another viewpoint, since the crystal grain of the small grain layer has a small grain size, a contact area of the small grain layer with the barrier layer becomes large and the adhesion of the small grain layer to the barrier layer is strong.

Therefore, copper atoms are unlikely to migrate in the vicinity of an interface between the barrier layer and the copper layer, and a copper interconnection layer having high electromigration resistance is obtained.

### BRIEF DESCRIPTION OF THE DRAWINGS

FIG. 1 is a cross-sectional view showing a production process of a semiconductor device according to Example of the present invention.

FIG. 2 is a cross-sectional view showing a production process of a semiconductor device according to Example of the present invention.

FIG. 3 is a cross-sectional view showing a production process of a semiconductor device according to Example of the present invention.

FIG. 4 is a cross-sectional view showing a production process of a semiconductor device according to Example of the present invention.

FIG. 5 is a cross-sectional view showing a production process of a semiconductor device according to Example of the present invention.

FIG. 6 is a TEM photograph (a magnification of 1000000) showing a cross section of a copper layer at a barrier layer interface according to Example of the present invention.

FIG. 7 is a graph showing the results of a reliability test of interconnections according to Example of the present invention and a conventional example.

### DESCRIPTION OF THE REFERENCE NUMERALS AND SYMBOLS

1: semiconductor substrate

3: element separating region

5: interlayer dielectric film

7: lower layer buried interconnection

9, 13: SiN film

11,15: FSG film

17: SiON film

21: connecting hole

23: upper layer interconnection groove

25: barrier layer

27: copper seed layer

27a: first copper layer

27b: second copper layer

29: copper-plated layer

### Best Mode for Carrying Out the Invention

### 1. First Embodiment

A semiconductor device of a first embodiment of the present invention is a semiconductor device comprising an interconnection layer formed by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer comprises a plurality of layers including a small grain layer and a large grain layer, having different crystal grain sizes from each other, and the small grain layer is in contact with the barrier layer.

### 1-1. Substrate, Insulating Film

As a substrate, various substrates, which are used for producing a semiconductor device, such as a Si substrate or a GaAs substrate can be used.

A material and a forming method of the insulating film on the substrate is not particularly limited. The insulating film can be formed from, for example, BPSG or FSG, which are generally used for forming an interlayer dielectric film. A method of forming the interlayer dielectric film is not particularly limited, and a CVD method or an application method may be used. A method of forming a groove or a hole of the insulating film is not particularly limited, and the groove or the hole can be formed by use of, for example, a photolithography technique and an etching technique. The shape of the groove or the hole is not particularly limited. Only either the groove or the hole may be formed or both of them may be formed.

### 1-2. Barrier Layer

The barrier layer is formed on the insulating film at least within the groove or the hole and generally formed on the whole area of the substrate with the insulating film thereon. The barrier layer has a function of preventing copper atoms of the copper seed layer and the like from diffusing into the substrate to contaminate the substrate. A material or a formation method of the barrier layer is not particularly limited as long as it can realize such a function. The barrier layer can be formed from a high melting point metal such as tantalum nitride or tantalum. Specifically, for example, the barrier layer can be formed in a monolayer structure of, for example, tantalum nitride or tantalum, or in a laminated structure of tantalum nitride and tantalum. Each layer of the barrier layers of the monolayer structure or laminated structure can be formed by, for example, a sputtering method.

### 1-3. Copper Seed Layer

The copper seed layer is generally polycrystalline and includes a plurality of layers including a small grain layer and a large grain layer, having different crystal grain sizes from each other. The copper seed layer may be two-layered or three- or more-layered. “The small grain layer” refers to a layer having a smaller average grain size than that of the large grain layer, and “the large grain layer” refers to a layer having a larger average grain size than that of the small grain layer. Further, “the grain size” refers to a diameter of a circumcircle of the crystal grain, and “the average crystal grain size” refers to an average of grain sizes of crystal grains included in a prescribed range. The grain sizes of crystal grains included in “the small grain layer” and “the large grain layer” are not particularly limited, and these grain sizes are about 0.2 to 1 nm and about 0.1 to 10 μm. And, the term “a plurality of layers” includes not only the case where an interface between adjacent two layers is clear but also the case where the crystal grain size varies gradually between adjacent two layers and an interface between adjacent two layers is not clear. Therefore, for example, the case where the crystal grain size in the vicinity of the bottom face (face which is closer to the barrier layer) of the copper seed layer is very small and it increases gradually toward the top face of the copper seed layer is also included in the scope of the present invention. A thickness of the small grain layer is preferably 0.2 to 1 nm, and more preferably 0.2 to 0.6 nm. The reason for this is that if the thickness of the small grain layer is within this range, the small grain layer exerts its function effectively.

The small grain layer and the large grain layer can be formed by a chemical vapor deposition method (CVD method) (for example, metal organic chemical vapor deposition method (MOCVD method)) or a sputtering method. The small grain layer and the large grain layer can be formed by the same methods or different methods. Examples of the case where these layers are formed by the different methods include a case where the small grain layer is formed by a sputtering method and the large grain layer is formed by a CVD method, and a converse case.

When both the small grain layer and the large grain layer are formed by a sputtering method, for example, if energy (high-frequency power or the like) applied in forming a first layer is set at lower energy than energy applied in forming a second layer, the first layer becomes a small grain layer and the second layer becomes a large grain layer. It is thought that this effect is produced because in the case of sputtering by small energy, a crystal grain which reaches the substrate has small energy and thereby the aggregation of the crystal grains is unlikely to occur. In other words, the copper seed layer is formed by a plurality of sputtering including sputtering with small energy and sputtering with large energy, and the sputtering with small energy is performed at the start of sputtering. The term “sputtering with small energy” refers to sputtering in which energy applied in sputtering is smaller than sputtering with large energy. “Sputtering with large energy” is a converse case. In accordance with this method, a small grain layer is formed in contact with the barrier layer. The transition from the sputtering with small energy to the sputtering with large energy may be set by changing energy to be applied discontinuously or may be set by changing energy to be applied gradually.

In addition, the term “copper” used herein includes alloys containing copper in addition to pure copper.

### 1-4 Copper-Plated Layer

The copper-plated layer can be formed by a publicly known electrolytic plating method by use of the above-mentioned copper seed layer.

### 1-5. Removals of Copper-Plated Layer and Copper Seed Layer on the Surface

Since the copper-plated layer and the copper seed layer are generally formed on the whole area of the substrate, portion of the layers (the copper-plated layer and the copper seed layer on the surface) outside the groove or the hole is removed to form an interconnection layer. In the present specification, the term “interconnection layer” refers to a layer including at least one of an interconnection and a connecting electrode. When the groove is formed in the insulating film, the interconnection layer includes the interconnection. When the hole is formed in the insulating film, the interconnection layer includes the connecting electrode. When the groove and the hole are formed in the insulating film, the interconnection layer includes the interconnection and the connecting electrode.

And, in this step, preferably, the barrier layer on the surface is also removed. The removals of the unnecessary copper layer and the barrier layer on the surface are performed by, for example, a chemical mechanical polishing method.

### 2. Second Embodiment

A semiconductor device of a second embodiment of the present invention comprises an insulating film, a barrier layer, a copper seed layer, and a copper-plated layer in this order on a substrate, wherein the copper seed layer comprises a plurality of layers including a small grain layer and a large grain layer, having different crystal grain sizes from each other, and the small grain layer is in contact with the barrier layer.

The description about the first embodiment holds true for the second embodiment as long as it is not against its purport. This embodiment has a copper layer where electromigration is unlikely to occur in a heat treatment. Like this embodiment, application of the present invention is not limited to the formation of the interconnection layer.

### EXAMPLE 1

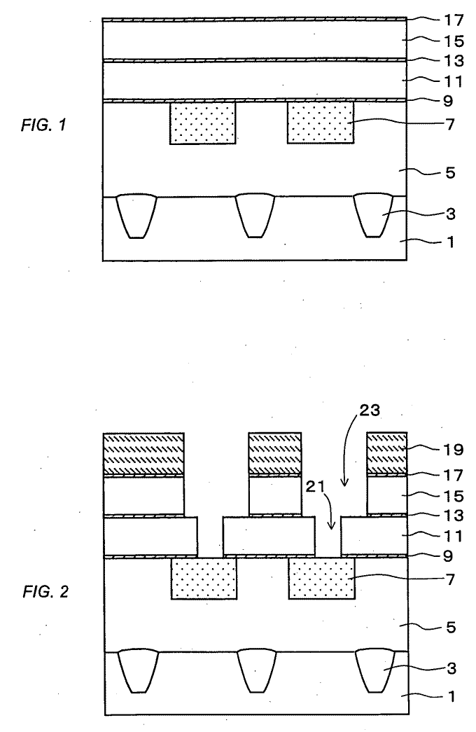

Hereinafter, Example of the present invention will be described referring to FIGS. 1 to 5. FIGS. 1 to 5 are cross-sectional views showing a production process of a semiconductor device of this example. Shape, film thicknesses, temperatures, materials or methods shown in drawings or descriptions below are just exemplifications, and the scope of the present invention is not limited to those shown in the drawings or the descriptions below.

### 1. Step of Forming Insulating Film

As shown in FIG. 1, a lower layer buried interconnection 7 is formed in a part of an upper section of an interlayer dielectric film 5 formed on a semiconductor substrate 1 such as silicon, on which an element separating region 3 and a semiconductor element (not shown) are formed. Furthermore, a SiN film 9 of 50 nm in thickness is deposited on the interlayer dielectric film 5 by a CVD method, and then a FSG film 11 of 400 nm in thickness, a SiN film 13 of 50 nm in thickness, a FSG film 15 of 400 nm in thickness, and a SiON film 17 of 65 nm in thickness are deposited in turn by a CVD method. The SiN film 9 prevents metal atoms composing the lower layer buried interconnection 7 from diffusing into the FSG film 11, and the SiN film 13 functions as a dry etching stopper film in damascene groove-processing.

### 2. Step of Forming Connecting Hole and Interconnection Groove

Next, as shown in FIG. 2, a connecting hole 21 between interconnections is formed in the laminated FSG film 11, SiN film 13, FSG film 15 and SiON film 17 by use of a known photolithography technique and dry etching technique. Subsequently, an upper layer interconnection groove 23 is formed in an interlayer dielectric laminated film, in which the connecting hole 21 is formed, also by use of a known photolithography technique and dry etching technique, and then the SiN film 9 at the bottom of the connecting hole 21 is removed by use of a known dry etching technique to form a groove and a hole for an upper layer buried interconnection.

### 3. Step of Forming Barrier Layer

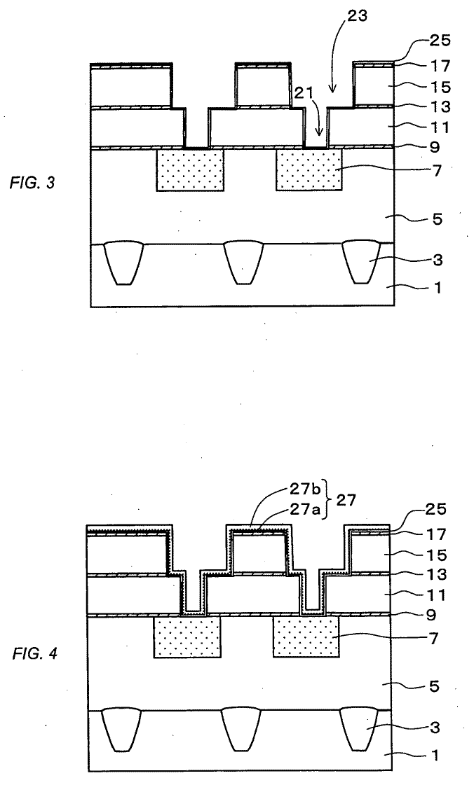

Next, as shown in FIG. 3, a barrier layer 25 made of TaN is deposited on the surface of the substrate including inner surfaces of the upper layer interconnection groove 23 and the connecting hole 21. The barrier layer 25 is formed in a film thickness of 25 to 35 nm in the conditions that an Ar gas flow rate is 56 sccm, a N₂ gas flow rate is 36 sccm, a pressure is 4 mTorr, a high-frequency power for generating plasma is 2500 W and a substrate temperature is 100° C., for example, by a reactive ionized sputtering method in which a Ta target is used.

### 4. Step of Forming Copper Seed Layer

Next, as shown in FIG. 4, a copper seed layer 27 is formed on the barrier layer 25. The copper seed layer 27 is formed by a two-stage step. First, by a self ionized sputtering method in which a copper target is used, a copper layer is formed for about 2 seconds in the conditions that an Ar gas flow rate is 48 sccm, a pressure is 6 mTorr, a high-frequency power for generating plasma is 1000 W and a substrate temperature is 20° C. Thereby, a first copper layer 27a having a thick of about 0.4 nm is formed. Next, a second copper layer 27b is formed in a film thickness of 100 to 150 nm under the same vacuum in the conditions that an Ar gas flow rate is 48 sccm, a pressure is 6 mTorr, a high-frequency power for generating plasma is 2400 W and an AC bias is 50 W.

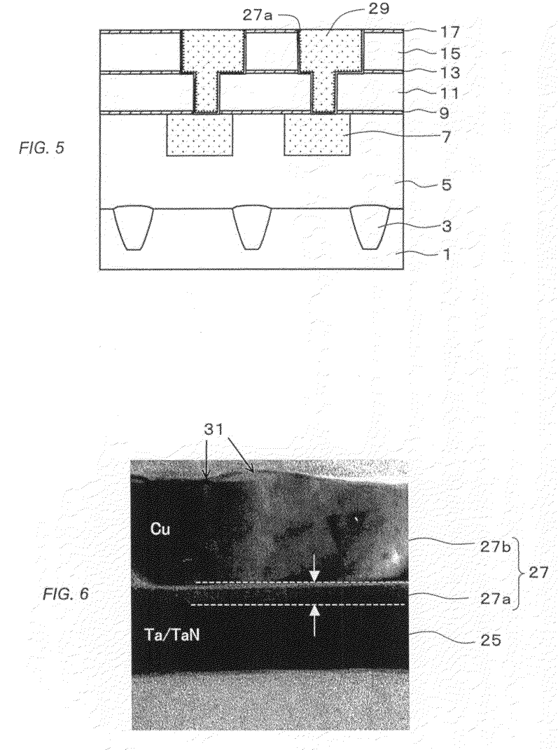

A TEM photograph (a magnification of 1000000) of the copper layer obtained by formation under the above-mentioned conditions is shown in FIG. 6. Referring to FIG. 6, it is found that in the second copper layer 27b, a grain boundary 31 is observed, and a grain size of a crystal grain is of the order of several microns. On the other hand, in the first copper layer 27a, the grain boundary is not observed. The grain boundary is not observed in the first copper layer 27a, but it has been identified from the results of XRD measurements separately performed that the first copper layer 27a is a crystal phase. Therefore, it is found that the first copper layer 27a is made of crystal grains having very small grain size (it is thought to be of the order of roughly several nanometers). It is thought that the grain size of the first copper layer 27a becomes smaller than that of the second copper layer 27b because a high frequency power inputted in forming the first copper layer 27a was small and therefore the aggregation of copper atoms did not proceed and crystal did not grow so much.

### 5. Step of Forming Copper-Plated Layer

Next, as shown in FIG. 5, a copper-plated layer 29 is formed by filling copper into the hole 21 and the groove 23 by an electrolytic plating method using the copper seed layer 27 formed in the above-mentioned step as an electrode. Thereafter, a heat treatment for stabilization in the subsequent CMP step is performed at 150° C. and at a pressure of 100 Torr for 15 minutes in an atmosphere of H₂. In this example, since the first copper layer 27a having a small crystal grain size is provided on the barrier layer 25 and the first copper layer 27a is unlikely to aggregate in a heat treatment, an adhesion property between the barrier layer 25 and the first copper layer 27a is secured after the heat treatment.

### 6. Step of CMP

Then, the formation of an interconnection layer including the copper buried interconnection and the connecting electrode is completed by removing the copper-plated layer 29, the copper seed layer 27 and the barrier layer 25 on the surface by use of a CMP method.

Further, a copper buried laminated interconnection whose interconnections are electrically connected one another via connecting electrodes can be formed by performing the above-mentioned steps repeatedly by the number of required metal interconnection layers.

In the above-mentioned Example, the case where TaN was used as the barrier layer has been described, but other high melting point metals (for example, Ta, TaSiN, Ti, TiN, TiSiN, W, WN, WSiN, Ru, RuO, etc.) may be used. Further, in the above-mentioned Example, the case where the first copper layer 27a is formed by a sputtering method has been described as an example, but it is considered that the electromigration resistance is improved also in the case where the first copper layer 27a having a small grain size is formed on the barrier layer by a CVD method such as a metal organic chemical vapor deposition method (MOCVD method) or the like.

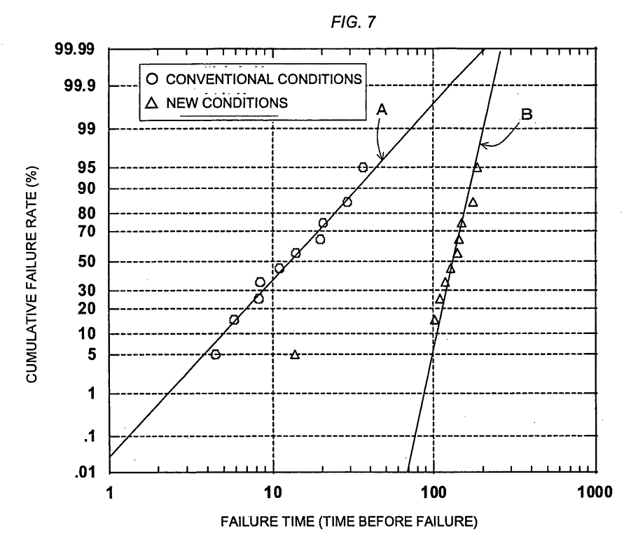

Next, a test for determining the electromigration resistance was performed under the conditions of producing a current density of about 1 MA/cm² by a current density of 0.81 mA at 230° C. using semiconductor devices produced under the conditions shown in the above-mentioned Example and semiconductor devices produced by the conventional art. The results of the test are shown in FIG. 7.

Data on each sample is used to be plotted as a curve on a Log-Log scale. An X-axis indicates a time during which stress is applied before failure and a Y-axis indicates a cumulative failure rate. Transition to right side on the X-axis means the increase in the electromigration resistance. Data under the conventional conditions are plotted in a circle and these dada form a curve A. The results of the semiconductor devices according to the present invention are plotted in a triangle and these dada form a curve B.

Referring to FIG. 7, the curve B is moved to the right side of the curve A, and this means that in the semiconductor devices according to the present invention, a time before a failure is extended. This increase in time before a failure is recognized throughout a range of a cumulative failure rate. This shows that the electromigration resistance is enhanced as a result of the process of this Example.

By the way, this application claims priority to Japanese application number 2005-58007, filed on Mar. 2, 2005, which is herein incorporated by reference.

1. A semiconductor device comprising an interconnection layer formed by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer comprises a plurality of layers including a small grain layer and a large grain layer, having different crystal grain sizes from each other, and the small grain layer is in contact with the barrier layer.

2. A semiconductor device comprising an insulating film, a barrier layer, a copper seed layer, and a copper-plated layer in this order on a substrate, wherein the copper seed layer comprises a plurality of layers including a small grain layer and a large grain layer, having different crystal grain sizes from each other, and the small grain layer is in contact with the barrier layer.

3. The device of claim 1, wherein the small grain layer has a thickness of 0.2 to 1 nm.

4. The device of claim 1, wherein the small grain layer and the large grain layer are formed by a chemical vapor deposition method or a sputtering method.

5. The device of claim 1, wherein the small grain layer and the large grain layer are formed by a sputtering method, and energy applied in forming the small grain layer is smaller than energy applied in forming the large grain layer.

6. The device of claim 1, wherein the copper-plated layer and the copper seed layer on the surface is removed by a chemical mechanical polishing method.

7. The device of claim 1, wherein the barrier layer is made of a high melting point metal.

8. A method of producing a semiconductor device comprising the step of forming an interconnection layer by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer comprises a plurality of layers including a small grain layer and a large grain layer, having different crystal grain sizes from each other, and the small grain layer is in contact with the barrier layer.

9. A method of producing a semiconductor device comprising the step of forming an interconnection layer by forming a groove or a hole in an insulating film formed on a substrate, forming a barrier layer on the resulting substrate, forming a copper seed layer on the barrier layer, forming a copper-plated layer by an electrolytic plating method by use of this copper seed layer, and removing the copper-plated layer and the copper seed layer on the surface, wherein the copper seed layer is formed by a plurality of sputtering including sputtering with small energy and sputtering with large energy, and the sputtering with small energy is performed at the start of sputtering.

10. A method of producing a semiconductor device comprising the step of forming an insulating film, a barrier layer, a copper seed layer, and a copper-plated layer in this order on a substrate, wherein the copper seed layer is formed by a plurality of sputtering including sputtering with small energy and sputtering with large energy, and the sputtering with small energy is performed at the start of sputtering.

11. The method of claim 8, wherein the small grain layer has a thickness of 0.2 to 1 nm.

12. The method of claim 8, wherein the copper seed layer is formed by a chemical vapor deposition method or a sputtering method.

13. The method of claim 8, wherein the small grain layer and the large grain layer are formed by a sputtering method, and energy applied in forming the small grain layer is smaller than energy applied in forming the large grain layer.

14. The method of claim 8, wherein the copper-plated layer and the copper seed layer on the surface is removed by a chemical mechanical polishing method.

15. The method of claim 8, wherein the barrier layer is made of a high melting point metal.
